(19) United States
(12) Patent Application Publication
(10) Pub. No.: US 2023/0138127 A1
(43) Pub. Date: May 4, 2023

(54) INFORMATION PROCESSING METHOD AND INFORMATION PROCESSING APPARATUS INCLUDING ACQUIRING A TIME SERIES DATA GROUP MEASURED DUIRNG A PROCESSING CYCLE FOR A SUBSTRATE

(71) Applicant: Tokyo Electron Limited, Tokyo (JP)

(72) Inventor: Hitoshi YONEMICHI, Sapporo City (JP)

(73) Assignee: Tokyo Electron Limited, Tokyo (JP)

(21) Appl. No.: 18/090,537

(22) Filed: Dec. 29, 2022

Related U.S. Application Data
(63) Continuation of application No. PCT/JP2021/023137, filed on Jun. 18, 2021.

(30) Foreign Application Priority Data
Jul. 2, 2020 (JP) 2020-114579

(51) Int. Cl. G06F 30/367

(52) U.S. Cl. CPC G06F 30/367

(57) ABSTRACT

An information processing method acquires a time series data group measured during a processing cycle for a substrate. The information processing method calculates a statistical value in each cycle of the processing cycle for each of time series data included in the acquired time series data group. The information processing method generates statistical data based on the calculated statistical value. The information processing method divides the generated statistical data or time series data into predetermined sections. The information processing method calculates a representative value for each section based on the divided statistical data or time series data.

### CROSS-REFERENCE TO RELATED APPLICATIONS

This application is a bypass continuation application of international application No. PCT/JP2021/023137, having an international filing date of Jun. 18, 2021, and designating the United States, the international application being based upon and claiming the benefit of priority from Japanese Patent Application No. 2020-114579, filed on Jul. 2, 2020, the entire contents of each are incorporated herein by reference.

### TECHNICAL FIELD

The present disclosure relates to an information processing method and an information processing apparatus.

### BACKGROUND

In a manufacturing process for a semiconductor device, there is an atomic layer deposition (ALD) method in which a thin unit layer that is a substantially monomolecular layer is repeatedly stacked on a substrate by switching between a plurality of processing gases. Further, there is atomic layer etching (ALE) that repeats etching of a thin unit layer, which is almost a monomolecular layer, on a layer formed on a substrate. In the ALD and ALE, predetermined processing is performed by repeatedly executing the same processing for one substrate.

### PATENT DOCUMENT OF THE RELATED ART

Patent Document 1: JP-A-2012-209593

### SUMMARY

### Technical Problem

The present disclosure provides an information processing method and an information processing apparatus capable of improving accuracy of feature value extraction of a time series data group measured during repetitive processing.

An information processing method according to an aspect of the present disclosure acquires a time series data group measured during a processing cycle for a substrate. The information processing method calculates a statistical value in each cycle of the processing cycle for each of time series data included in the acquired time series data group. The information processing method generates statistical data based on the calculated statistical value. The information processing method divides the generated statistical data or time series data into predetermined sections. The information processing method calculates a representative value for each section based on the divided statistical data or time series data.

According to the present disclosure, it is possible to improve the accuracy of feature value extraction of the time series data group measured during repetitive processing.

### BRIEF DESCRIPTION OF THE DRAWINGS

FIG. 1 is a block diagram illustrating an example of an information processing system according to an embodiment of the present disclosure.

FIG. 2 is a block diagram illustrating an example of a hardware configuration of an information processing apparatus according to an embodiment of the present disclosure.

FIG. 3 is a functional block diagram illustrating an example of a functional configuration of the information processing apparatus according to the embodiment of the present disclosure.

FIG. 4 is a diagram illustrating an example of time series data.

FIG. 5 is a diagram illustrating an example in which a part of the time series data is enlarged.

FIG. 6 is a diagram illustrating an example of calculation of statistical values from the time series data.

FIG. 7 is a diagram illustrating an example of a section set by Bayesian optimization.

FIG. 8 is a diagram illustrating an example of a relationship between representative values of sections and measurement data.

FIG. 9 is a diagram illustrating an example of a case where the representative values of sections of statistical data are obtained from the time series data.

FIG. 10 is a diagram illustrating an example by comparison with the related art in detection of abnormality of a process.

FIG. 11 is a flowchart illustrating an example of feature value extraction processing according to the present embodiment.

FIG. 12 is a flowchart illustrating an example of prediction processing according to the present embodiment.

### DETAILED DESCRIPTION

Hereinafter, embodiments of an information processing method and an information processing apparatus disclosed herein will be described in detail with reference to the drawings. The disclosed technology is not limited to the following embodiments.

In a process of repeatedly performing processing such as the ALD and ALE, a cycle of injecting processing gas, reacting by inputting energy such as heat, and purging the processing gas is repeated hundreds of times in a short time, and therefore, time series data representing tick of a process is greatly increased. Therefore, cycles of similar tendency are repeated very finely for the time series data, and thus, it is difficult to extract a portion that contributes to important features such as a defect or performance of a process even when the time series data is referred to as it is. For example, in Patent Document 1, when a sub-recipe is repeatedly executed, feature values are extracted from the time series data by using data of a specific number of times out of execution times of the sub-recipe. However, the extracted feature values are not the feature values for the entire repetitive processing. Accordingly, in a case where similar cycles are repeated several hundred times, it is difficult to extract feature values that accurately reflect a processing state. Further, it is difficult to determine how many times processing data is used for the processing that is repeatedly performed several hundred times. That is, because accuracy of feature value extraction is low, deep knowledge and time are required to perform setting regarding the process. Therefore, it is expected to improve the accuracy of feature value extraction of a time series data group measured during the repetitive processing.

### Configuration of Information Processing System 1

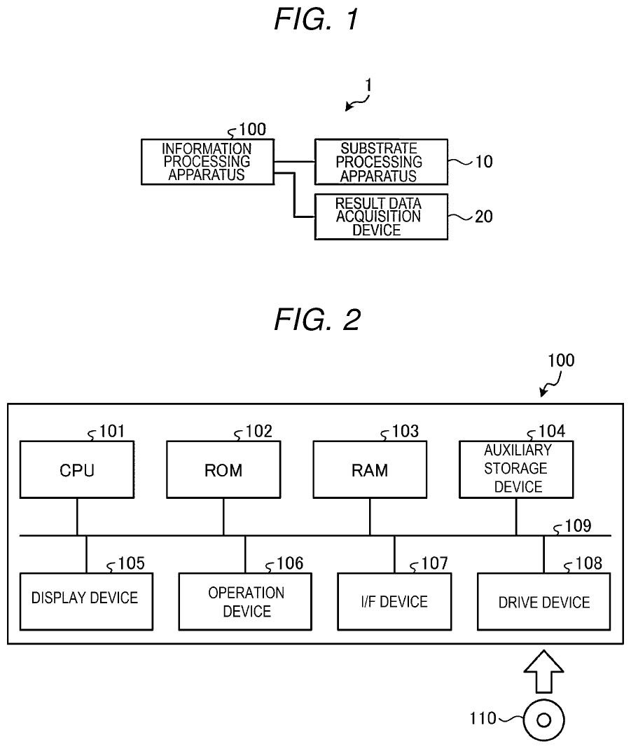

FIG. 1 is a block diagram illustrating an example of an information processing system according to an embodiment of the present disclosure. An information processing system 1 illustrated in FIG. 1 includes a substrate processing apparatus 10, a result data acquisition device 20, and an information processing apparatus 100. The substrate processing apparatus 10, the result data acquisition device 20, and the information processing apparatus 100 may each be plural. The substrate processing apparatus 10 is, for example, a layer formation device or an etching device configured to perform a process of atomic layer deposition (ALD) or atomic layer etching (ALE) on a substrate (a semiconductor wafer, hereinafter referred to as a wafer) of a processing target. The substrate processing apparatus 10 performs process processing on a wafer and transmits a time series data group measured during the processing to the information processing apparatus 100.

The result data acquisition device 20 performs a predetermined inspection (for example, a layer formation rate) on the substrate in which the processing is ended in the substrate processing apparatus 10 so as to acquire result data. The result data acquisition device 20 transmits the acquired result data to the information processing apparatus 100 as data for model generation.

The information processing apparatus 100 receives the time series data group from the substrate processing apparatus 10 and receives the result data from the result data acquisition device 20. Based on various types of information of the received time series data group and so on, the information processing apparatus 100 extracts feature values and generates a model for outputting a prediction result regarding a result of a process. Further, the information processing apparatus 100 receives a new time series data group from the substrate processing apparatus 10 and outputs the prediction result regarding the result of the process in the substrate processing apparatus 10 based on the received new time series data group. The prediction result includes, for example, abnormality detection information of a process, and various types of prediction information on a wafer or a substrate processing apparatus.

### Hardware Configuration of Information Processing Apparatus 100

FIG. 2 is a block diagram illustrating an example of a hardware configuration of an information processing apparatus according to an embodiment of the present disclosure. As illustrated in FIG. 2, the information processing apparatus 100 includes circuitry such as a central processing unit (CPU) 101, a read only memory (ROM) 102, and a random access memory (RAM) 103. A processor (a processing circuit or processing circuitry) such as the CPU 101, and a memory such as the ROM 102 and the RAM 103 constitute a so-called computer.

Furthermore, the information processing apparatus 100 includes an auxiliary storage device 104, a display device 105, an operation device 106, an interface (UF) device 107, and a drive device 108. The devices of hardware in the information processing apparatus 100 are connected to each other via a bus 109.

The CPU 101 is an arithmetic device that executes various programs (for example, a prediction program and the like) installed in the auxiliary storage device 104.

The ROM 102 is a nonvolatile memory, and serves as a main memory device. The ROM 102 stores various types of programs, data, and the like necessary for the CPU 101 to execute the various types of programs installed in the auxiliary storage device 104. Specifically, the ROM 102 stores boot programs and the like such as BIOS (basic input/output system) and EFI (extensible firmware interface).

The RAM 103 is a volatile memory such as a DRAM (dynamic random access memory) and an SRAM (static random access memory), and serves as a main memory device. The RAM 103 provides a work area to which the various types of programs installed in the auxiliary storage device 104 are loaded when executed by the CPU 101.

The auxiliary storage device 104 stores various types of programs, and stores various types of data and the like used when the various types of programs are executed by the CPU 101. For example, a time series data group storage to be described below is implemented in the auxiliary storage device 104.

The display device 105 is a display device that displays an internal state of the information processing apparatus 100. The operation device 106 is an input device used when a manager of the information processing apparatus 100 inputs various types of instructions to the information processing apparatus 100. The I/F device 107 is a connection device for connecting to, and communicating with, a network (not shown).

The drive device 108 is a device to which a recording medium 110 is set. Here, the recording medium 110 includes a medium for optically, electrically, or magnetically recording information, such as a CD-ROM, a flexible disk, a magneto-optical disk, or the like. The recording medium 110 may also include a semiconductor memory or the like that electrically records information, such as a ROM, a flash memory, or the like.

The various types of programs to be installed in the auxiliary storage device 104 are installed by the drive device 108 reading the various types of programs recorded in the recording medium 110 upon the recording medium 110 being supplied and set in the drive device 108, for example. Alternatively, the various types of program to be installed in the auxiliary storage device 104 may be installed upon being downloaded via a network.

### Functional Configuration of Information Processing Apparatus 100

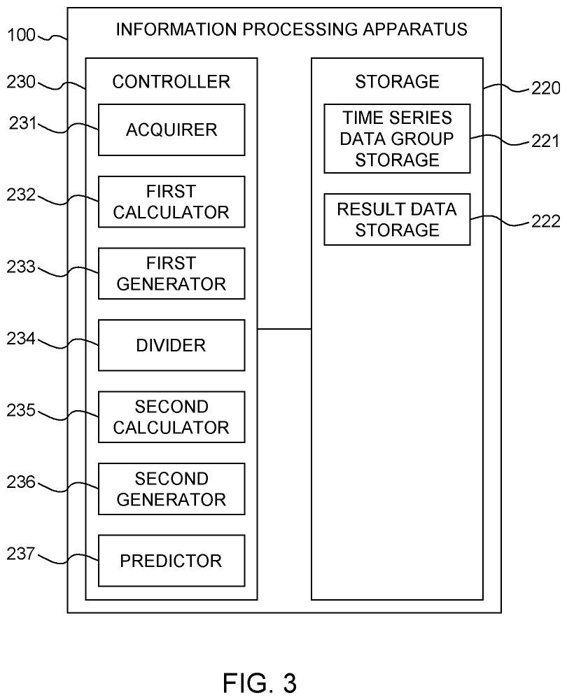

FIG. 3 is a functional block diagram illustrating an example of a functional configuration of the information processing apparatus according to the embodiment of the present disclosure. The information processing apparatus 100 includes a storage 220 and a controller 230.

The storage 220 is implemented by, for example, the RAM 103, a semiconductor memory element such as a flash memory, and a storage device such as a hard disk or an optical disk. The storage unit includes a time series data group storage 221 and a result data storage 222. Further, the storage 220 stores information used for processing at the controller 230. The controller 230 is implemented by, for example, the CPU 101.

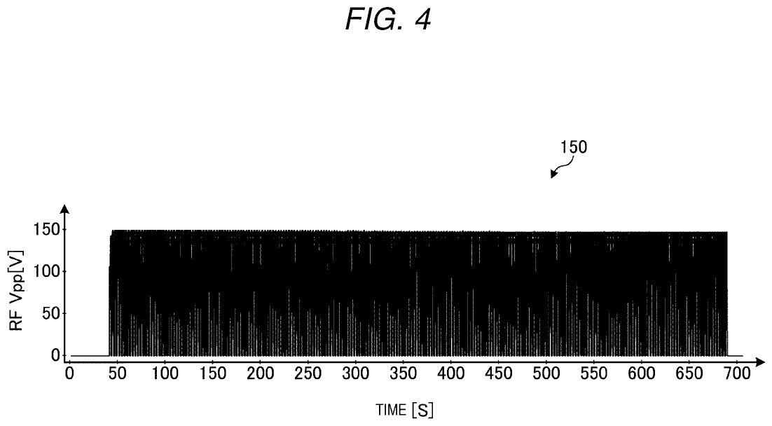

The time series data group storage 221 stores respective time series data groups measured in a process of performing a processing cycle for a plurality of wafers in the substrate processing apparatus 10. As the time series data included in the time series data group, the time series data group storage 221 stores information, for example, a voltage (RF Vpp) of a high frequency power supply of the substrate processing apparatus 10. FIG. 4 is a diagram illustrating an example of time series data. As an example of time series data, a graph 150 illustrated in FIG. 4 is a graph of a voltage of the high frequency power supply according to time elapse of a process, that is, the processing cycle.

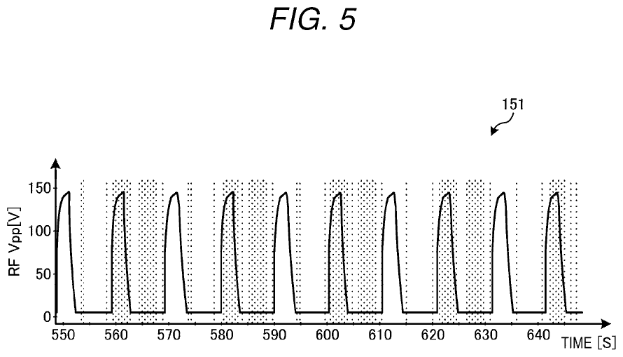

FIG. 5 is a diagram illustrating an example in which a part of the time series data is enlarged. A graph 151 illustrated in FIG. 5 is a partially enlarged graph of the graph 150 illustrated in FIG. 4. As illustrated in the graph 151, it turns out that the voltage of the high frequency power supply repeats a cycle with a peak. The time series data groups respectively corresponding to wafers are stored in the time series data group storage 221 in association with a wafer number.

Referring back to FIG. 3, the result data storage 222 stores result data regarding a result of a process for each wafer. As the result data, for example, various types of measurement data can be used such as measurement data like a layer thickness regarding performance of a wafer in which a process is completed. The data input from the operation device 106 or the I/F device 107 is stored as the result data.

The storage 220 additionally stores statistical data, information of a section, a model, and the like. The statistical data is data obtained by arranging in time series a statistical value in each cycle of the processing cycle calculated for each of time series data. That is, a trend of the entire time series data can be easily grasped by the statistical data. The information of the section is information for dividing the statistical data or time series data into predetermined sections. In the division of the sections, features of a process can be accurately grasped by adjusting a manner of the division. Further, accuracy of the model can be improved by using a representative value based on the statistical data or time series data of an appropriately divided section. The model is generated by performing multivariate analysis or machine learning based on the statistical data or time series data. In the generating of the model, the result data may be used. The model is generated by using, for example, a Mahalanobis distance based on 36 of a normal distribution of data. For example, in a case of abnormality detection, a model that detects abnormality can be used when the Mahalanobis distance continuously exceeds a threshold. Further, as the model, another model such as a linear regression model generated by using partial least squares (PLS) regression may be used.

The controller 230 is implemented when, for example, the CPU 101, a micro processing unit (MPU), a graphics processing unit (GPU) (graphics processor), or the like execute a program stored in an internal storage device by using the RAM 103 as a work area. Further, for example, the controller 230 may be implemented by an integrated circuit such as an application specific integrated circuit (ASIC) or a FIELD programmable gate array (FPGA).

The controller 230 includes an acquirer 231, a first calculator 232, a first generator 233, a divider 234, a second calculator 235, a second generator 236, and a predictor 237, and implements or executes a function and an operation of information processing to be described below. An internal configuration of the controller 230 is not limited to the configuration illustrated in FIG. 3 and may be another configuration as long as the internal configuration can perform the information processing to be described below.

In a case of feature value extraction processing, the acquirer 231 acquires respective time series data groups corresponding to respective wafers from the substrate processing apparatus 10. Further, the acquirer 231 may acquire result data of process processing of a substrate such as inspection data from the result data acquisition device 20. Furthermore, in a case of prediction processing, the acquirer 231 acquires a time series data group corresponding to a new wafer to be predicted from the substrate processing apparatus 10. The acquirer 231 stores the acquired time series data group in the time series data group storage 221 and stores the acquired result data in the result data storage 222.

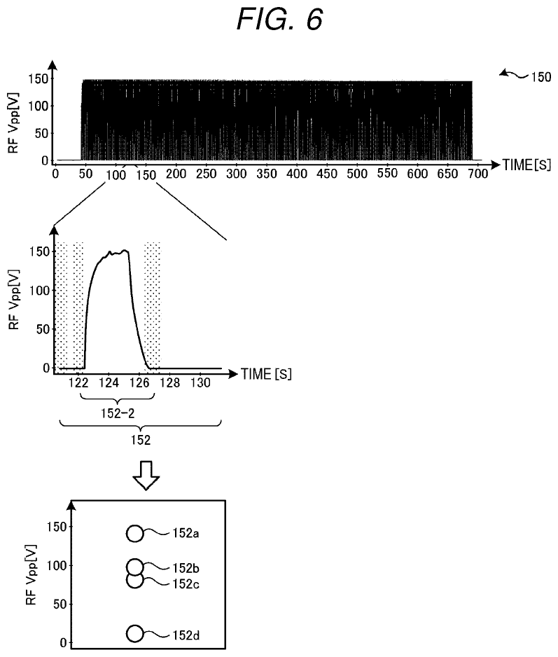

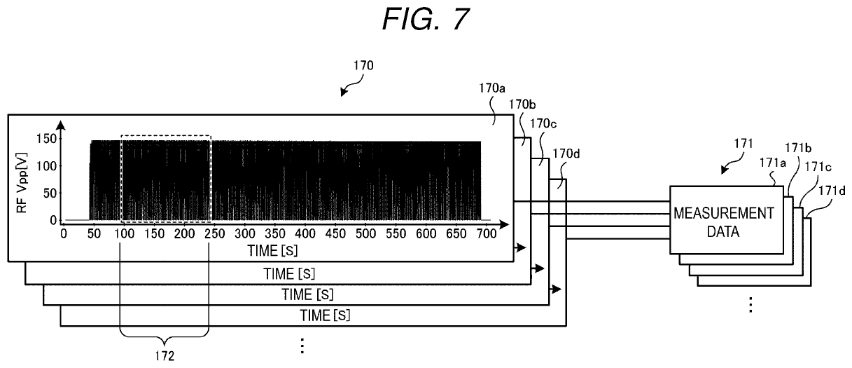

By referring to the time series data group storage 221, the first calculator 232 calculates the statistical value in each cycle of the processing cycle for each of the time series data included in the time series data group. For example, values such as an average value, a minimum value, a maximum value, a variance, and a gradient can be used as the statistical values. The first calculator 232 outputs a set of the calculated statistical values for the time series data to the first generator 233. In the feature value extraction processing, the statistical values for the time series data are calculated in a similar manner for each of the time series data groups in a plurality of wafers. Further, in the following description, in a case where processing of each processor is performed for each time series data in the time series data groups of the plurality of wafers or each time series data in the time series data group of one wafer, one time series data will be representatively described, and descriptions on the other time series data will be omitted. Here, calculation of statistical values will be described with reference to FIG. 6.

FIG. 6 is a diagram illustrating an example of calculation of statistical values from the time series data. As illustrated in FIG. 6, the first calculator 232 extracts, for example, a specific cycle 152 from the graph 150 of the time series data. With respect to the extracted cycle 152, the first calculator 232 calculates, as statistical values, values such as a maximum value 152a, a median value 152b, an average value 152c, and a minimum value 152d.

Further, the first calculator 232 may remove data to be excluded from the calculation of statistical values for each cycle included in the time series data. The data to be excluded can be, for example, data such as a step switching portion in the cycle. For example, the first calculator 232 may take out only a second step section 152-2 at a step switching timing in a cycle 152, exclude other data, and calculate statistical values.

Referring back to FIG. 3, when the set of the statistical values for the time series data is input from the first calculator 232, the first generator 233 generates the statistical data based on the set of the statistical values for the time series data. For example, the first generator 233 generates the statistical data corresponding to the time series data by arranging the statistical values in time series. The first generator 233 outputs the generated statistical data to the divider 234. The first generator 233 may be integrated with the first calculator 232.

When the statistical data is input from the first generator 233, the divider 234 divides the input statistical data into one or more sections. When it is desired to avoid a decrease in accuracy due to repeated statistical processing, the divider 234 may divide time series data included in a time series data group into one or more sections by referring to the time series data group storage 221. In the case of the feature value extraction processing, the divider 234 divides the statistical data or time series data into sections based on a manner of the division for a predetermined sections. Further, in a case where the second generator 236 instructs to change the manner of the division for the sections, the divider 234 divides the statistical data or time series data into the sections, for example, by changing a ratio of division, the number of divisions, and the like. For example, the divider 234 divides the statistical data or time series data into two sections in the first half of a process, one section in the middle part thereof, and two sections in the second half thereof. In this case, for example, a section I1 indicates a first cycle of a process, and a section I2 indicates a section from a second cycle to a 10^{th} cycle on a head side. A section I3 indicates a section from an 11^{th} cycle on the head side to an 11^{th} cycle on a tail side. That is, the section I3 includes the majority of several hundred cycles constituting the process. A section I4 indicates a section from a second cycle to the 10^{th} cycle on the tail side, and a section I5 indicates the last cycle on the tail side. In the aforementioned division of the sections, features of the process can be accurately grasped by adjusting the manner of the division. In the case of the prediction processing, the divider 234 divides the statistical data or time series data into sections based on the information of the sections stored in the storage 220. The divider 234 outputs the divided statistical data or divided time series data to the second calculator 235.

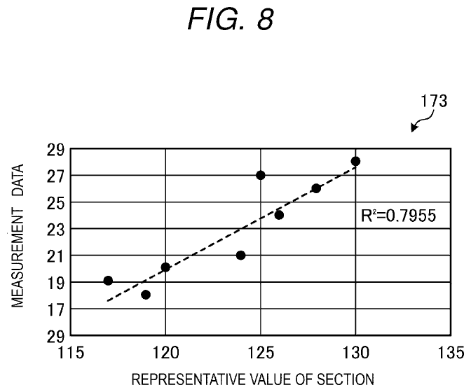

In a case where a section previously obtained by Bayesian optimization is used as the information of the sections for dividing the statistical data or time series data, the divider 234 calculates the section in advance by referring to the time series data group storage 221 and the result data storage 222. Hereinafter, setting of the sections by Bayesian optimization will be described with reference to FIGS. 7 and 8.

FIG. 7 is a diagram illustrating an example of a section set by Bayesian optimization. As illustrated in FIG. 7, a time series data group 170 and a measurement data group 171 respectively have the same wafer numbers associated with each other. That is, time series data 170a, 170b, 170c, 170d, . . . are respectively associated with measurement data 171a, 171b, 171c, 171d, . . . Further, the time series data group 170 and the measurement data group 171 use a data group of a plurality of wafers, for example, a data group of three to several tens of wafers. The divider 234 performs Bayesian optimization by using the time series data group 170 as an explanatory function and using the measurement data group 171 as an objective function.

The divider 234 performs the Bayesian optimization by using, for example, a range (section) of a cycle to be extracted as a parameter. In the same manner as the second calculator 235 to be described below, the divider 234 calculates a representative value of a section. The divider 234 determines a relationship between the calculated representative value of the section and measurement data, for example, by using a determination coefficient R². The determination coefficient R² ranges from 0 to 1.

FIG. 8 is a diagram illustrating an example of a relationship between representative values of sections and measurement data. In the example of a graph 173 illustrated in FIG. 8, it is assumed that the determination coefficient R² is 0.7955. In this case, for example, the divider 234 changes the above-described parameters to perform a search until the determination coefficient R² becomes 0.8 or more or until a preset number of times and calculation times are satisfied. That is, the divider 234 sets a predetermined section such that a prediction error of a model is reduced. In addition to the determination coefficient R², a root mean square error (RMSE) or PLS may be used as a relationship between the representative values of the sections and the measurement data.

The divider 234 can obtain, as a result of Bayesian optimization, for example, a section 172 illustrated in FIG. 7 as section information for dividing the statistical data or time series data. The divider 234 stores the calculated section 172 in the storage 220. That is, in the example of the section 172, the number of prediction targets in the model can be reduced from five to one, compared to the above-described sections I1 to I5. That is, search time can be shortened by using Bayesian optimization. Instead of the Bayesian optimization, the divider 234 may obtain a section for dividing the statistical data or time series data by using another parameter searching method.

Referring back to FIG. 3, when the divided statistical data or time series data is input from the divider 234, the second calculator 235 calculates the representative value (summary) for each section based on the divided statistical data or time series data. As representative values for each section, the second calculator 235 calculates values such as an average value, a minimum value, a maximum value, a variance, and a gradient. For example, in a case where the statistical data or time series data are divided into the above-described sections I1 to I5, the second calculator 235 calculates the average value as a representative value for each of the sections I1 to I5. The second calculator 235 outputs the calculated representative value for each section to the second generator 236 in the feature value extraction processing, and outputs the representative value to the predictor 237 in the prediction processing.

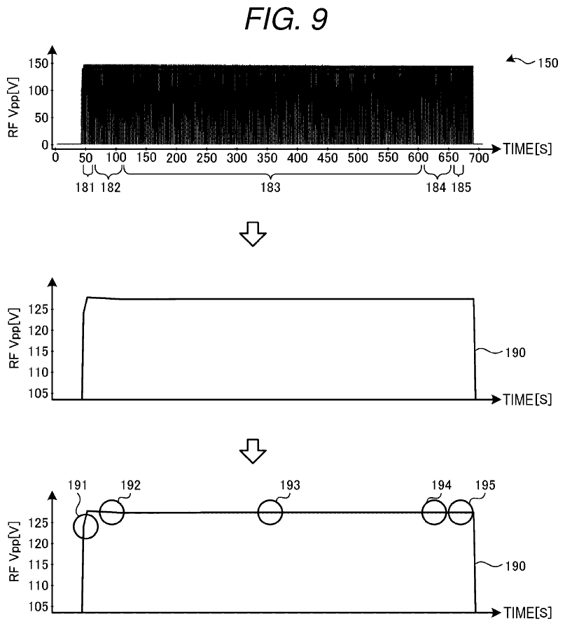

Hereinafter, a case where the representative value of the section of the statistical data is obtained from the time series data will be described with reference to FIG. 9. FIG. 9 is a diagram illustrating an example of a case where the representative values of sections of statistical data are obtained from the time series data. As illustrated in FIG. 9, the information processing apparatus 100 calculates statistical data 190 based on statistical values of respective cycles from the graph 150 of the time series data. Next, the information processing apparatus 100 calculates, for example, representative values 191 to 195 for sections 181 to 185 corresponding to the above-described sections I1 to I5. In the example of FIG. 9, the representative value 191 indicates a lower value as compared with the other representative values 192 to 195 in the statistical data 190. This indicates that the section 181 of the representative value 191, that is, a voltage of the high frequency power supply at a first cycle of a process is low and rise of plasma is poor. That is, a wafer with statistical data 190 is defective due to the wafer being processed in the process in which the rise of plasma is abnormal; thus, in such a case, abnormality is to be detected.

Referring back to FIG. 3, the second generator 236 receives a representative value for each section from the second calculator 235 in the feature value extraction processing. The second generator 236 performs multivariate analysis based on a representative value for each section based on the statistical data or time series data to generate the model. The model is, for example, a prediction function f(x). The prediction function f(x) is a function that employs, for example, a Mahalanobis distance, PLS regression, and the like. Further, in a case of using the result data, by referring to the result data storage 222, the second generator 236 performs multivariate analysis based on the representative value for each section based on the statistical data or time series data and based on the result data so as to generate the model. The second generator 236 inputs, as x, the representative value for each section that is a feature value, to the generated model, that is, the prediction function f(x), and obtains y=f(x). Y represents a prediction result. With respect to the prediction result, the second generator 236 determines whether or not prediction accuracy is higher than or equal to a threshold by using an evaluation function such as RMSE. When it is determined that the prediction accuracy is not greater than or equal to the threshold, the second generator 236 instructs the divider 234 to change the manner of the division for the sections. When it is determined that the prediction accuracy is greater than or equal to the threshold, the second generator 236 stores the information of the sections and the model in the storage 220.

The predictor 237 receives the representative value for each section from the second calculator 235 in the prediction processing. The predictor 237 inputs, as x, the representative value for each section that is the feature value, to the prediction function f(x) that is a model used when the feature value stored in the storage 220 is extracted, and obtains the prediction result, that is, y=f(x). The predictor 237 determines whether or not the prediction result is greater than or equal to the threshold. When it is determined that the prediction result is greater than or equal to the threshold, the predictor 237 outputs the prediction result, and executes the following preset operation, for example: a change of a set value of a recipe in the substrate processing apparatus 10; notifying an alarm to the substrate processing apparatus 10; and sending a mail to an operator. When it is determined that the prediction result is not greater than or equal to the threshold, the predictor 237 outputs the prediction result and does not execute the preset operation.

Depending on used models, the prediction result includes the following information: abnormality detection information of a process; prediction information regarding a result of a process; prediction information for a maintenance period of the substrate processing apparatus 10; correction information in a set value of the substrate processing apparatus 10; and correction information in a set value of a process. Further, information that classifies abnormality of a process may be output as the prediction result. The prediction result can be used for various purposes: for example, the result is stored in the storage 220 to be used for other processing of statistical processing and the like, or is transmitted to the substrate processing apparatus 10 to be used for correction in a set value.

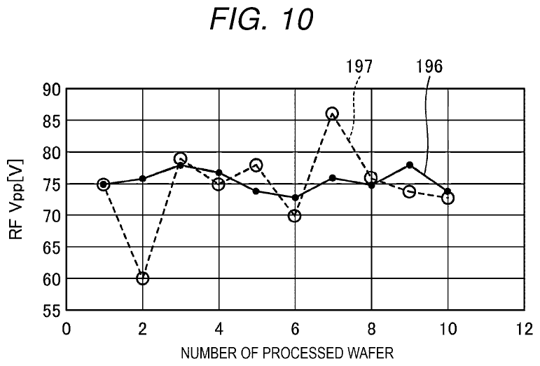

Here, an example of the prediction result will be described with reference to FIG. 10. FIG. 10 is a diagram illustrating an example by comparison with the related art in detection of abnormality of a process. As illustrated in FIG. 10, for example, in a case where the abnormality detection information of the process is used as the prediction result, the summary 197, which is a prediction result generated in the present embodiment, can detect the occurrence of an abnormality because the second and seventh wafers are deviated from the population, as compared with the summary 196 generated from the entire conventional time series data.

### Feature Value Extraction Method

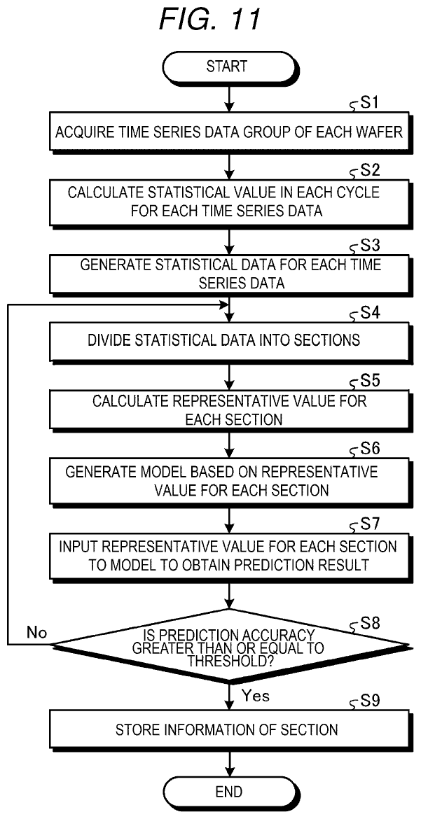

Next, an operation of the information processing apparatus 100 according to the present embodiment will be described. First, the feature value extraction processing will be described with reference to FIG. 11. FIG. 11 is a flowchart illustrating an example of feature value extraction processing according to the present embodiment. FIG. 11 will be described by taking a case where the statistical data is divided into sections as an example.

The acquirer 231 of the information processing apparatus 100 acquires time series data groups respectively corresponding to wafers from the substrate processing apparatus 10 (step S1). In a case of using result data, the acquirer 231 acquires the result data for each wafer from the result data acquisition device 20. The acquirer 231 stores the acquired time series data group in the time series data group storage 221 and stores the acquired result data in the result data storage 222.

By referring to the time series data group storage 221, the first calculator 232 calculates statistical values in each cycle of a processing cycle for each of time series data included in a time series data group (step S2). The first calculator 232 outputs a set of the calculated statistical values for the time series data to the first generator 233.

When the set of the statistical values for the time series data is input from the first calculator 232, the first generator 233 generates the statistical data based on the set of the statistical values for the time series data (step S3). The first generator 233 outputs the generated statistical data to the divider 234.

When the statistical data is input from the first generator 233, the divider 234 divides the input statistical data into one or more sections (step S4). The divider 234 outputs the divided statistical data to the second calculator 235.

When the divided statistical data is input from the divider 234, the second calculator 235 calculates the representative value for each section based on the divided statistical data (step S5). The second calculator 235 outputs the calculated representative value for each section to the second generator 236.

When the representative value for each section are input from the second calculator 235, the second generator 236 performs multivariate analysis based on the representative value for each section to generate a model (prediction function f(x)) (step S6). In a case of using result data, the second generator 236 performs multivariate analysis based on the representative value for each section and the result data by referring to the result data storage 222 to generate the model. The second generator 236 inputs the representative value (a feature value x) for each section to the generated model (f(x)) to obtain a prediction result. That is, y=f(x) is obtained (step S7).

With respect to the prediction result, the second generator 236 determines whether or not prediction accuracy is greater than or equal to a threshold by using an evaluation function such as RMSE (step S8). When it is determined that the prediction accuracy is not greater than or equal to the threshold (step S8: No), the second generator 236 returns to step S4 and restarts from the section division. When it is determined that the prediction accuracy is greater than or equal to the threshold (step S8: Yes), the second generator 236 stores information of sections and the model in the storage 220 and ends the feature value extraction processing. In this way, the information processing apparatus 100 can improve accuracy of feature value extraction of a time series data group measured during repetitive processing.

### Prediction Method

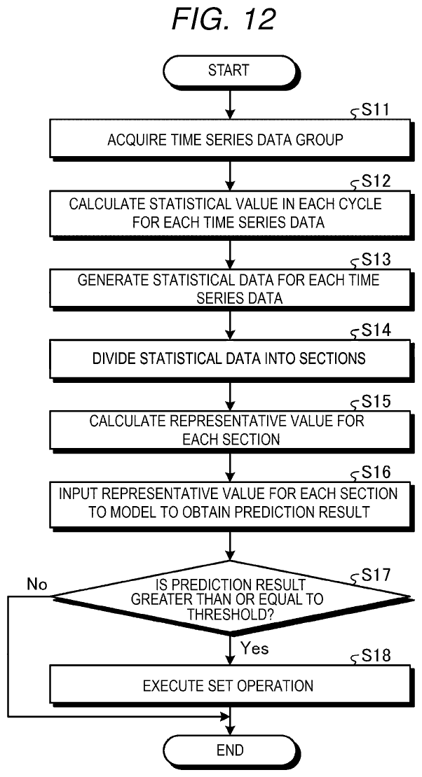

Next, the prediction processing will be described with reference to FIG. 12. FIG. 12 is a flowchart illustrating an example of prediction processing according to the present embodiment. FIG. 12 will be described by taking a case where the statistical data is divided into sections as an example.

The acquirer 231 of the information processing apparatus 100 acquires a time series data group corresponding to a wafer from the substrate processing apparatus 10 (step S11). The acquirer 231 stores the acquired time series data group in the time series data group storage 221.

By referring to the time series data group storage 221, the first calculator 232 calculates a statistical value in each cycle of the processing cycle for each of the time series data included in the time series data group by the same manner as that in the extraction of the feature value (step S12). The first calculator 232 outputs a set of the calculated statistical values for the time series data to the first generator 233.

When the set of statistical values for the time series data is input from the first calculator 232, the first generator 233 generates the statistical data based on the set of the statistical values for the time series data (step S13). The first generator 233 outputs the generated statistical data to the divider 234.

The divider 234 divides the input statistical data into the same sections as that in the extraction of the feature value (step S14). The divider 234 outputs the divided statistical data to the second calculator 235.

When the divided statistical data is input from the divider 234, the second calculator 235 calculates the representative value for each section based on the divided statistical data by the same manner as that in the extraction of the feature value (step S15). The second calculator 235 outputs the calculated representative value (the feature value x) for each section to the predictor 237.

When the representative value for each section is input from the second calculator 235, the predictor 237 inputs the representative value for each section to a model used when the feature value is extracted so as to obtain a prediction result (step S16). That is, the feature value x is substituted into y=f(x). The predictor 237 determines whether or not a prediction result is greater than or equal to a threshold (step S17). When it is determined that the prediction result is greater than or equal to the threshold (step S17: Yes), the predictor 237 executes a preset operation (step S18) and ends the prediction processing. The preset operation includes: a change in the set value of the recipe in the substrate processing apparatus 10; notifying the substrate processing apparatus 10 of an alarm; sending a mail to an operator, and the like. Meanwhile, when it is determined that the prediction result is not greater than or equal to the threshold (step S17: No), the predictor 237 ends the prediction processing without performing an operation in particular. In this way, the information processing apparatus 100 can improve the accuracy of feature value extraction of a time series data group measured during repetitive processing and can perform abnormality detection, prediction, and the like by using the prediction result.

As described above, according to the present embodiment, the information processing apparatus 100 acquires a time series data group measured during the processing cycle for a substrate. Further, the information processing apparatus 100 calculates a statistical value in each cycle of the processing cycle for each of the time series data included in the acquired time series data group. Further, the information processing apparatus 100 generates statistical data based on the calculated statistical values. Further, the information processing apparatus 100 divides the generated statistical data or time series data into predetermined sections. Further, the information processing apparatus 100 calculates representative values for each section based on the divided statistical data or time series data. The calculated representative values represent features of a process in the processing cycle performed for a substrate. As a result, it is possible to improve the accuracy of feature value extraction of the time series data group measured during the repetitive processing.

Further, according to the present embodiment, the information processing apparatus 100 further acquires result data regarding a result of a process for a substrate. Further, the information processing apparatus 100 generates a model based on the calculated representative value for each section and the result data. As a result, it is possible to generate a model that improves the accuracy of feature value extraction of the time series data group measured during the repetitive processing.

Further, according to the present embodiment, the information processing apparatus 100 sets a predetermined section such that a prediction error of the model is reduced. As a result, it is possible to further improve the accuracy of feature value extraction of a time series data group.

Further, according to the present embodiment, the information processing apparatus 100 divides the statistical data or time series data into respective sections of at least a first half, a middle part, and a second half. As a result, feature values at a head and a last tail of time series data can be accurately extracted.

Further, according to the present embodiment, the information processing apparatus 100 obtains a section by Bayesian optimization. As a result, it is possible to obtain a section regardless of the known knowledge.

Further, according to the present embodiment, the information processing apparatus 100 uses at least one of multivariate analysis and neural networking. As a result, it is possible to further improve the accuracy of feature value extraction of a time series data group.

Further, according to the present embodiment, a statistical value is any one of an average value, a minimum value, a maximum value, a variance, and a gradient in each cycle. As a result, a feature value can be extracted according to features of time series data, and thus, accuracy can be further improved.

Further, according to the present embodiment, the representative value is any one of an average value, a minimum value, a maximum value, a variance, and a gradient in a predetermined section. As a result, a feature value can be extracted according to features of time series data, and thus, accuracy can be further improved.

Further, according to the present embodiment, the information processing apparatus 100 acquires the time series data group measured during the processing cycle performed for a new substrate. Further, the information processing apparatus 100 calculates a statistical value in each cycle of the processing cycle for each of the time series data included in the acquired time series data group. Further, the information processing apparatus 100 generates statistical data based on the calculated statistical values. Further, the information processing apparatus 100 divides the generated statistical data or time series data into predetermined sections. Further, the information processing apparatus 100 calculates representative values for each section based on the divided statistical data or time series data. Further, the information processing apparatus 100 inputs the calculated representative value for each section to a model and outputs a prediction result. As a result, prediction can be performed more accurately.

Further, according to the present embodiment, the prediction result is one or more of: abnormality detection information of a process; prediction information regarding a process result; prediction information for a maintenance period of the substrate processing apparatus 10; correction information of a set value of the substrate processing apparatus 10; and correction information in a set value of a process. As a result, abnormality in a process can be detected. Further, a processing plan of a wafer can be easily constructed. Further, a maintenance period of the substrate processing apparatus 10 can be easily known. Further, set values of the substrate processing apparatus 10 and a process can be corrected.

The embodiments disclosed herein are exemplary in all respects and can be considered to be non-restrictive. The embodiments described above may be omitted, replaced, or modified in various forms without departing from the scope and idea of the appended claims.

Further, in the embodiments described above, a voltage of a high frequency power supply of the substrate processing apparatus 10 is provided as one example of time series data but the present embodiment is not limited thereto. For example, information relating to performance for a wafer, such as a flow rate of processing gas and pressure in a chamber can be used as time series data.

Further, in the embodiment described above, a model is generated by using multivariate analysis but the present disclosure is not limited thereto. For example, according to abnormality detection, a trained model is generated by machine learning such as a convolutional neural network (CNN) by using as training data a set of a plurality of statistical data and measurement data and abnormal or normal information, and abnormality may be detected by using the generated learnt model as a model. Furthermore, abnormality detection by a trend chart focusing on one measurement data may be combined.

Further, in the embodiment described above, with respect to the predetermined sections that divide the statistical data, a preset case and a case obtained by Bayesian optimization are described, but the present disclosure is not limited thereto. For example, in various processes, a trained model is generated by machine learning such as CNN by using as training data a set of statistical data and a section obtained by Bayesian optimization, and a predetermined section in statistical data of a new process may be determined by using the generated learned model.

Further, in the embodiment described above, the information processing apparatus 100, which acquires time series data from the substrate processing apparatus 10, performs data processing such as the feature value extraction processing and prediction processing, but the present disclosure is not limited thereto. For example, a controller of the substrate processing apparatus 10 may perform various types of data processing such as the feature value extraction processing and prediction processing described above.

Further, in the embodiment described above, an example is described in which a semiconductor wafer is used as a substrate of a processing target in the substrate processing apparatus 10, but the present disclosure is not limited thereto. For example, time series data may be acquired from a substrate processing apparatus in which a substrate such as a flat panel display (FPD) is used as processing target.

Furthermore, all or a certain part of various processing functions performed by each device may be performed by a CPU (or a microcontroller such as an MPU or a micro controller unit (MCU)). Further, it is needless to say that all or a certain part of various processing functions may be performed on a program analyzed and executed by a CPU (or a microcontroller such as an MPU or an MCU) or on hardware by a wired logic.

The present disclosure is not limited to only the above-described embodiments, which are merely exemplary. It will be appreciated by those skilled in the art that the disclosed systems and/or methods can be embodied in other specific forms without departing from the spirit of the disclosure or essential characteristics thereof. The presently disclosed embodiments are therefore considered to be illustrative and not restrictive. The disclosure is not exhaustive and should not be interpreted as limiting the claimed invention to the specific disclosed embodiments. In view of the present disclosure, one of skill in the art will understand that modifications and variations are possible in light of the above teachings or may be acquired from practicing of the disclosure.

Reference to an element in the singular is not intended to mean “one and only one” unless explicitly so stated, but rather “one or more.” Moreover, where a phrase similar to “at least one of A, B, or C” is used in the claims, it is intended that the phrase be interpreted to mean that A alone may be present in an embodiment, B alone may be present in an embodiment, C alone may be present in an embodiment, or that any combination of the elements A, B and C may be present in a single embodiment; for example, A and B, A and C, B and C, or A and B and C.

No claim element herein is to be construed under the provisions of 35 U.S.C. 112(f) unless the element is expressly recited using the phrase “means for.” As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

The scope of the invention is indicated by the appended claims, rather than the foregoing description.

1. An information processing method comprising:
acquiring a time series data group measured during a processing cycle for a substrate;
calculating a statistical value in each cycle of the processing cycle for each of time series data included in the acquired time series data group;
generating statistical data based on the calculated statistical value;
dividing the generated statistical data into predetermined sections; and
calculating a representative value for each of the sections based on the divided statistical data, wherein the acquiring further includes:
acquiring result data regarding a result of a process for the substrate; and
generating a model based on the calculated representative value for each of the sections and the result data.

2. The information processing method according to claim 1, wherein the dividing includes: setting the predetermined sections such that a prediction error of a model is reduced.

3. The information processing method according to claim 1, wherein the dividing includes:
dividing the statistical data or the time series data into respective sections of at least a first half, a middle part, and a second half.

4. The information processing method according to claim 1, wherein the dividing obtains the sections by Bayesian optimization.

5. The information processing method according to claim 1, wherein the generating the model uses at least one of multivariate analysis and neural networking.

6. The information processing method according to claim 1, wherein the statistical value is any one of an average value, a minimum value, a maximum value, a variance, and a gradient in each of the cycles.

7. The information processing method according to claim 1, wherein the representative value is any one of an average value, a minimum value, a maximum value, a variance, and a gradient in the predetermined sections.

8. An information processing method comprising:
acquiring a time series data group measured during a processing cycle for a new substrate;
calculating a statistical value in each cycle of the processing cycle for each of time series data included in the acquired time series data group;
generating statistical data based on the calculated statistical value;
dividing the generated statistical data or time series data into predetermined sections;
calculating a representative value for each of the sections based on the divided statistical data or time series data; and
inputting the calculated representative value for each of the sections to a model and outputting a prediction result.

9. The information processing method according to claim 8, wherein the prediction result is one or more of: abnormality detection information of a process; prediction information regarding a result of the process; prediction information for a maintenance period of a substrate processing apparatus; correction information in a set value of the substrate processing apparatus; and
correction information in a set value of the process.

10. An information processing apparatus comprising:
an acquirer that acquires a time series data group measured during a processing cycle for a substrate;
a first calculator that calculates a statistical value in each cycle of the processing cycle for each of time series data included in the acquired time series data group;
a first generator that generates statistical data based on the calculated statistical value;
a divider that divides the generated statistical data into predetermined sections; and
a second calculator that calculates a representative value for each of the sections based on the divided statistical data,
wherein the acquirer further acquires result data regarding a result of a process for the substrate, and
the information processing apparatus further comprises a second generator that generates a model based on the calculated representative value for each of the sections and the result data.

11. The information processing apparatus according to claim 10, wherein the divider sets the predetermined sections such that a prediction error of a model is reduced.

12. The information processing apparatus according to claim 10, wherein the divider divides the statistical data or the time series data into respective sections of at least a first half, a middle part, and a second half.

13. An information processing apparatus comprising:
an acquirer that acquires a time series data group measured during a processing cycle for a new substrate to be predicted;
a first calculator that calculates a statistical value in each cycle of the processing cycle for each of time series data included in the acquired time series data group;
a generator that generates statistical data based on the calculated statistical value;
a divider that divides the generated statistical data or time series data into predetermined sections;
a second calculator that calculates a representative value for each of the sections based on the divided statistical data or time series data; and
a predictor that inputs the calculated representative value for each of the sections to a model and outputs a prediction result.

14. The information processing apparatus according to claim 13, wherein the prediction result is one or more of: abnormality detection information of a process; prediction information regarding a result of the process; prediction information for a maintenance period of a substrate processing apparatus; correction information in a set value of the substrate processing apparatus; and correction information in a set value of the process.

15. The information processing method according to claim 2, wherein the dividing includes:
dividing the statistical data or the time series data into respective sections of at least a first half, a middle part, and a second half.

16. The information processing method according to claim 2, wherein the dividing obtains the sections by Bayesian optimization.

17. The information processing method according to claim 3, wherein the dividing obtains the sections by Bayesian optimization.

18. The information processing method according to claim 2, wherein the statistical value is any one of an average value, a minimum value, a maximum value, a variance, and a gradient in each of the cycles.

19. The information processing method according to claim 3, wherein the statistical value is any one of an average value, a minimum value, a maximum value, a variance, and a gradient in each of the cycles.

20. The information processing method according to claim 4, wherein the statistical value is any one of an average value, a minimum value, a maximum value, a variance, and a gradient in each of the cycles.
